(19) United States
(12) Patent Application Publication
(10) Pub. No.: US 2013/0337229 A1
(43) Pub. Date: Dec. 19, 2013

(54) ROUGHED CURED MATERIAL AND LAMINATED

(71) Applicants: Takayuki Kobayashi, Tsukuba (JP); Koichi Shibayama, Tsukuba (JP); Shuichiro Matsumoto, Kyoto (JP)

(72) Inventors: Takayuki Kobayashi, Tsukuba (JP); Koichi Shibayama, Tsukuba (JP); Shuichiro Matsumoto, Kyoto (JP)

(73) Assignee: SEKISUI CHEMICAL CO., LTD., Osaka, (JP)

(21) Appl. No.: 13/982,909

(22) PCT Filed: Jan. 27, 2012
(86) PCT No.: PCT/JP2012/051787

§ 371 Date: Aug. 28, 2013

(30) Foreign Application Priority Data
Feb. 2, 2011 (JP) 2011-021001
Feb. 2, 2011 (JP) 2011-021002

(51) Int. Cl. H05K 1/03

(52) U.S. Cl. CPC H05K 1/0353
USPC 428/149; 428/418

(57) ABSTRACT

A roughened cured material allows reduction of surface roughness and increase in adhesive strength between a cured object and a metal layer. A roughened cured material is obtained by advancing curing of an epoxy resin material to obtain a preliminary-cured material and conducting roughening treatment on a surface of the preliminary-cured material. The epoxy resin material contains an epoxy resin, a curing agent, and a silica whose mean particle diameter is not smaller than 0.2 μm but not larger than 1.2 μm. When a roughening-treated surface of the roughened cured material is photographed with a scanning electron microscope, in a 5 μm×5 μm sized area of the roughening-treated surface in a photographed image, the number of particles of the silica that are exposed from the roughening-treated surface and whose exposed portions have a maximum length of 0.3 μM or longer in the image is not greater than 15.

### TECHNICAL FIELD

The present invention relates to a roughened cured material obtained by advancing curing of an epoxy resin material to obtain a preliminary-cured material and then conducting a roughening treatment on a surface of the preliminary-cured material, and a laminated body using the roughened cured material.

### BACKGROUND ART

Hitherto, various resin compositions are used in order to obtain electronic components such as laminated plates and printed wiring boards. For example, in multilayer printed wiring boards, resin compositions are used for forming insulation layers to insulate interlayers located internally, and for forming insulation layers located on surface layer portions.

As one example of such resin compositions, Patent Literature 1 described below discloses a resin composition containing an epoxy resin, a curing agent, a phenoxy resin, and an inorganic filler having a mean particle diameter of 0.01 to 2 μm. Furthermore, Patent Literature 1 also discloses a resin composition containing an epoxy resin, a curing agent, and an inorganic filler having a mean particle diameter of 0.1 to 10 μm.

In Patent Literature 1, each layer in a multilayer film having a two-layer laminated structure is formed using the above described different two types of resin compositions. It is disclosed that the multilayer film is finely embedded in gaps and the like provided on a substrate.

Patent Literature 2 described below discloses a resin composition containing an epoxy resin, a curing agent, at least one among a phenoxy resin and a polyvinyl acetal resin, and a phosphorus containing benzoxazine compound. Patent Literature 2 discloses that, when a roughening treatment is conducted on a cured object resulting from curing the resin composition, even though roughness of a roughened surface is relatively small, the roughened surface shows high adhesion force with respect to a plated conductor, and an insulation layer having excellent fire-resistance is obtained.

### CITATION LIST

### Patent Literature

[PTL 1] Japanese Laid-Open Patent Publication No. 2008-302677
[PTL 2] WO2009/038166A1

### SUMMARY OF THE INVENTION

### Problems to be Solved by the Invention

When the resin composition disclosed in Patent Literature 1 is preliminary-cured and a roughening treatment is conducted thereon, there are cases where the roughness of the roughened surface is not sufficiently small.

Although Patent Literature 2 discloses that the roughness is small when the resin composition has the above described composition, even when the resin composition disclosed in Patent Literature 2 is used, there are cases where the roughness of the roughened surface is not sufficiently small.

In addition, with the multilayer film disclosed in Patent Literature 1 and the resin composition disclosed in Patent Literature 2, when metal layers are formed on the surfaces of roughened cured material by using a plating process, there are cases where blistering of the metal layers occur or the metal layers are peeled off from the surfaces of cured objects. Thus, there are cases where it is difficult to sufficiently increase the adhesive strength between the cured objects and the metal layers.

An objective of the present invention is to provide: a roughened cured material that allows reduction of surface roughness of a roughening-treated surface thereof and increase in adhesive strength between a metal layer and a cured object resulting from curing the roughened cured material; and a laminated body using the roughened cured material.

### Solution to the Problems

According to a broad aspect of the present invention, provided is a roughened cured material obtained by advancing curing of an epoxy resin material to obtain a preliminary-cured material and then conducting a roughening treatment on a surface of the preliminary-cured material, wherein the epoxy resin material contains an epoxy resin, a curing agent, and a silica whose mean particle diameter is not smaller than 0.2 μm but not larger than 1.2 μm; and when the roughening-treated surface is photographed with a scanning electron microscope, in a 5 μm×5 μm sized area of a roughening-treated surface in a photographed image, a number of particles of the silica that are exposed from the roughening-treated surface and whose exposed portions have a maximum length of 0.3 μm or longer in the image is not greater than 15.

When the roughening-treated surface of the roughened cured material is photographed with a scanning electron microscope, in a 5 μm×5 μm sized area of the roughening-treated surface in a photographed image, a ratio of a number of particles of the silica that are exposed from the roughening-treated surface and whose exposed portions have a maximum length of 0.3 μm or longer in the image, to a total number of pores appearing in the image and particles of the silica appearing in the image, is preferably not greater than 20%.

Furthermore, wherein, when the roughening-treated surface of the roughened cured material is photographed with a scanning electron microscope, in a 5 μm×5 μm sized area of the roughening-treated surface in a photographed image, a ratio of a number of particles of the silica that are exposed from the roughening-treated surface and whose exposed portions have a maximum length of 0.3 μm or longer in the image, to a number of particles of the silica appearing in the image, is preferably not greater than 50%.

In a specific aspect of the roughened cured material according to the present invention, a contained amount of the silica in 100 weight % of total solid content contained in the epoxy resin material is not less than 55 weight % but not greater than 80 weight %.

In another specific aspect of the roughened cured material according to the present invention, an arithmetic mean roughness Ra of the roughening-treated surface is not larger than 0.3 μm, and a ten-point mean roughness Rz of the roughening-treated surface is not larger than 3.0 μm.

In still another specific aspect of the roughened cured material according to the present invention, a swelling treatment is conducted on the preliminary-cured material before the roughening treatment is conducted.

A laminated body according to the present invention includes: a cured object resulting from curing the roughened cured material formed in accordance with the present invention; and a metal layer laminated on a roughening-treated surface of the cured object. An adhesive strength between the cured object and the metal layer is preferably not less than 3.9 N/cm².

### Advantageous Effects of the Invention

The roughened cured material according to the present invention is obtained by advancing curing of an epoxy resin material to obtain a preliminary-cured material and conducting a roughening treatment on a surface of the preliminary-cured material; the epoxy resin material contains an epoxy resin, a curing agent, and a silica whose mean particle diameter is not smaller than 0.2 μm but not larger than 1.2 μm; and when the roughening-treated surface is photographed with a scanning electron microscope, in a 5 μm×5 μm sized area of a roughening-treated surface in a photographed image, a number of particles of the silica that are exposed from the roughening-treated surface and whose exposed portions have a maximum length of 0.3 μm or longer in the image is not greater than 15. Thus, it is possible to reduce the surface roughness of the roughening-treated surface of the roughened cured material. In addition, when a metal layer is formed on a surface of a cured object resulting from curing the roughened cured material, it is possible to increase the adhesive strength between the cured object and the metal layer.

### BRIEF DESCRIPTION OF THE DRAWINGS

FIG. 1(a) is a diagram schematically showing an image obtained by photographing, with a scanning electron microscope, a roughening-treated surface of a roughened cured material according to one embodiment of the present invention, and FIG. 1(b) is a partially-cutaway cross-sectional front view schematically showing the roughened cured material.

FIG. 2(a) s a diagram schematically showing an image obtained by photographing, with a scanning electron microscope, a roughening-treated surface of a roughened cured material according to another embodiment of the present invention, and FIG. 2(b) is a partially-cutaway cross-sectional front view schematically showing the roughened cured material.

FIG. 3 is a partially-cutaway cross-sectional front view schematically showing a laminated body using a roughened cured material according to one embodiment of the present invention.

### DESCRIPTION OF EMBODIMENTS

In the following, specific embodiments and examples of the present invention will be described with reference to the drawings to explain the present invention.

A roughened cured material according to the present invention is a roughened cured material obtained by advancing curing of an epoxy resin material to obtain a preliminary-cured material and then conducting a roughening treatment on a surface of the preliminary-cured material.

The epoxy resin material contains an epoxy resin, a curing agent, and a silica whose mean particle diameter is not smaller than 0.2 μm but not larger than 1.2 μm.

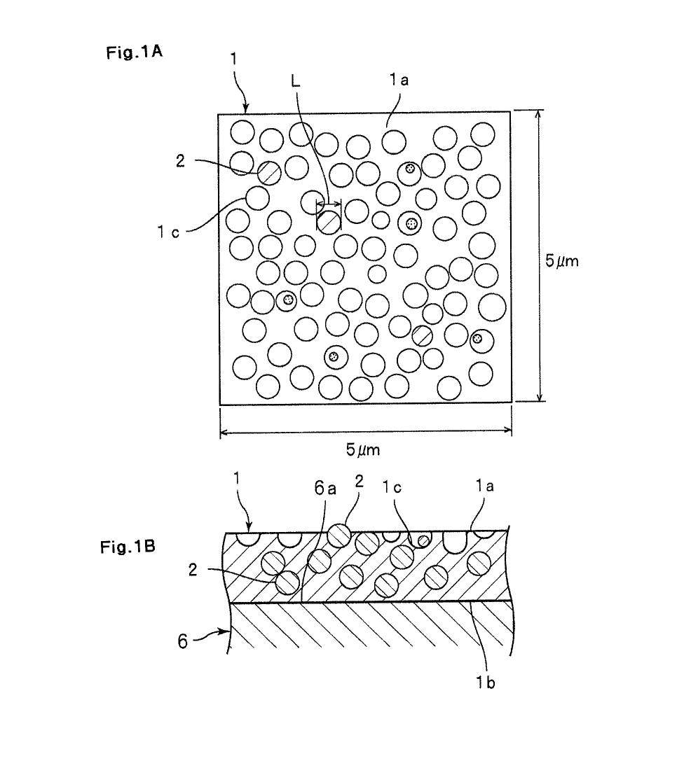

FIG. 1(a) is a diagram schematically showing an image obtained by photographing, with a scanning electron microscope, a roughening-treated surface of a roughened cured material according to one embodiment of the present invention. FIG. 1(b) is a partially-cutaway cross-sectional front view schematically showing the roughened cured material according to the embodiment of the present invention.

A roughened cured material 1 shown in FIG. 1 is laminated on an upper surface 6a of a lamination target object 6. The roughened cured material 1 has a first surface 1a and a second surface 1b. The first surface 1a is roughening-treated. The second surface 1b is in contact with the upper surface 6a of the lamination target object 6. The above epoxy resin material for obtaining the roughened cured material 1 contains an epoxy resin, a curing agent, and a silica 2 whose mean particle diameter is not smaller than 0.2 μm but not larger than 1.2 μm. It should be noted that in FIG. 1(a), the silica 2 indicated by oblique lines is exposed, and the exposed portions of the silica 2 indicated by oblique lines are shown. In FIG. 1(a), the silica 2 indicated by dots is silica that is not exposed but appears in the photographed image.

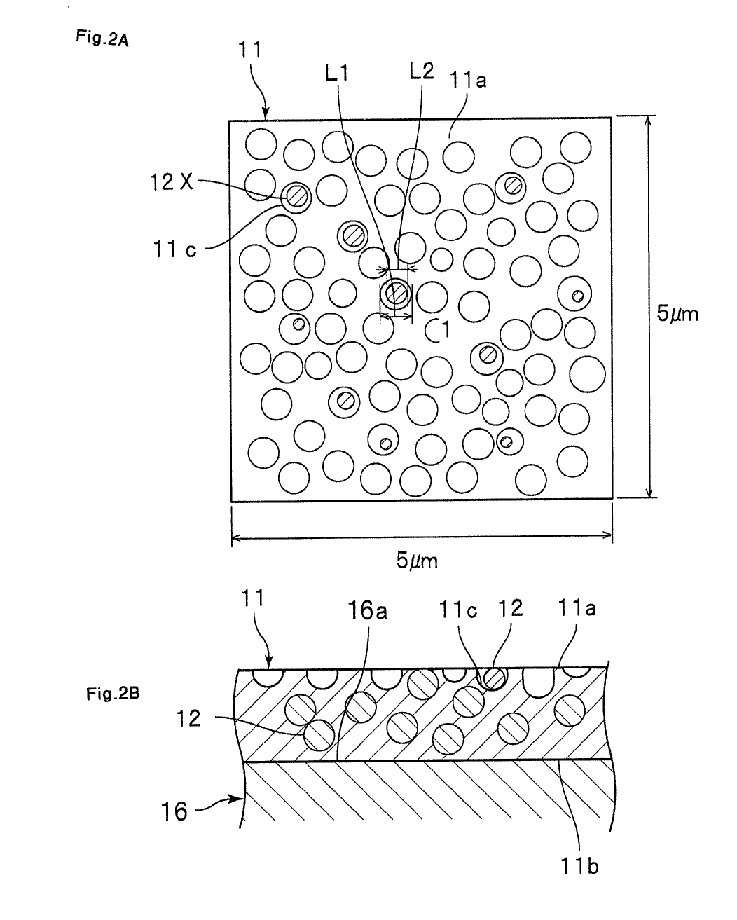

FIG. 2(a) is a diagram schematically showing an image obtained by photographing, with a scanning electron microscope, a roughening-treated surface of a roughened cured material according to another embodiment of the present invention. FIG. 2(b) is a partially-cutaway cross-sectional front view schematically showing the roughened cured material according to the embodiment of the present invention.

A roughened cured material 11 shown in FIG. 2 is laminated on an upper surface 16a of a lamination target object 16. The roughened cured material 11 has a first surface 11a and a second surface 11b. The first surface 11a is roughening-treated. The second surface 11b is in contact with the upper surface 16a of the lamination target object 16. The above epoxy resin material for obtaining the roughened cured material 11 contains an epoxy resin, a curing agent, and a silica 12 whose mean particle diameter is not smaller than 0.2 μm but not larger than 1.2 μm.

In each of the roughened cured materials 1 and 11, a plurality of pores 1c or 11c exist on each of the roughening-treated first surfaces 1a and 11a. In each of the plurality of pores 1c or 11c, no silica 2 or 12 exists, or the silica 2 or 12 exists. In each of the roughened cured materials 1 and 11, when each of the roughening-treated first surfaces 1a and 11a is photographed with a scanning electron microscope, in a 5 μm×5 μm sized area of the roughening-treated first surface 1a or 11a in the photographed image, the number of particles of the silica 2 or 12 that are exposed from the roughening-treated first surface 1a or 11a and whose exposed portions have a maximum length of 0.3 μm or longer in the image (hereinafter, sometimes denoted as silica particle number A) is not greater than 15.

From a standpoint of further reducing the surface roughness of the roughening-treated surface of the roughened cured material and further increasing the adhesive strength between a cured object and a metal layer, the silica particle number A is preferably not greater than 12 and more preferably not greater than 8. In addition, in the present invention, the silica particle number A is not 0 and may be not less than 1. Even when the silica particle number A is not less than 1, if the particle number A is not greater than 15, it is possible to reduce the surface roughness of the roughening-treated surface of the roughened cured material and to increase the adhesive strength between the cured object and the metal layer.

In addition, in each of the roughened cured materials 1 and 11, when each of the roughening-treated first surfaces 1a and 11a is photographed with a scanning electron microscope, in a 5 μm×5 μm sized area of the roughening-treated first surface 1a or 11a in the photographed image, the ratio of the number n of particles of the silica 2 or 12 that are exposed from the roughening-treated first surface 1a or 11a and whose exposed portions have a maximum length of 0.3 μm or longer in the image, to the total number Nb of the pores 1c or 11c appearing in the image and particles of the silica 2 or 12 appearing in the image, (hereinafter, sometimes denoted as silica particle number ratio B) is preferably not greater than 20%. In this case, the surface roughness of the roughening-treated surface of the roughened cured material is effectively reduced, and the adhesive strength between the cured object and the metal layer is effectively increased. The ratio B (%) is obtained by a formula: number n/total number Nb×100.

From a standpoint of further reducing the surface roughness of the roughening-treated surface of the roughened cured material and further increasing the adhesive strength between the cured object and the metal layer, the silica particle number ratio B is more preferably not greater than 15% and further preferably not greater than 10%. In addition, in the present invention, the silica particle number ratio B may not be 0%, may exceed 0%, or may exceed 1%. Even when the silica particle number ratio B exceeds 0% or exceeds 1%, if the ratio B is not greater than 20%, it is possible to effectively reduce the surface roughness of the roughening-treated surface of the roughened cured material and to effectively increase the adhesive strength between the cured object and the metal layer.

In addition, in each of the roughened cured materials 1 and 11, when each of the roughening-treated first surfaces 1a and 11a is photographed with a scanning electron microscope, in a 5 μm×5 μm sized area of the roughening-treated first surface 1a or 11a in the photographed image, the ratio of the number n of particles of the silica 2 or 12 that are exposed from the roughening-treated first surface 1a or 11a and whose exposed portions have a maximum length of 0.3 μm or longer in the image, to the number nc of particles of the silica 2 or 12 appearing in the image, (hereinafter, sometimes denoted as silica particle number ratio C) is preferably not greater than 50%. In this case, the surface roughness of the roughening-treated surface of the roughened cured material is effectively reduced, and the adhesive strength between the cured object and the metal layer is effectively increased. The ratio C (%) is obtained by a formula: number n/number nc×100.

From a standpoint of further reducing the surface roughness of the roughening-treated surface of the roughened cured material and further increasing the adhesive strength between the cured object and the metal layer, the silica particle number ratio C is more preferably not greater than 40% and further preferably not greater than 30%. In addition, in the present invention, the silica particle number ratio C may not be 0%, may exceed 0%, or may exceed 1%. Even when the silica particle number ratio C exceeds 0% or exceeds 1%, if the ratio C is not greater than 50%, it is possible to effectively reduce the surface roughness of the roughening-treated surface of the roughened cured material and to effectively increase the adhesive strength between the cured object and the metal layer.

When silica that is exposed on the roughening-treated surface of the roughened cured material exists, a plating solution is put on the exposed silica portion by a plating process for forming a metal layer. Thus, the adhesive strength between the cured object and the metal layer tends to be decreased, and further the metal layer located on the exposed silica portion becomes easy to peel off. When the silica particle number A is not greater than the above value, it is possible to form minute pores on the roughening-treated surface of the roughened cured material, and thus it is possible to reduce the surface roughness of the roughening-treated surface. As a result, the adhesive strength between the cured object and the metal layer is also increased. In addition, it is possible to prevent decrease in insulation properties that is caused by a roughening liquid remaining between the silica and the resin component. When the silica particle number ratio B or the silica particle number ratio C is not greater than the above value, it is possible to further effectively form minute pores on the roughening-treated surface of the roughened cured material and to effectively reduce the surface roughness of the roughening-treated surface. In order to reduce the surface roughness of the roughening-treated surface of the roughened cured material and further to increase the adhesive strength between the cured object and the metal layer, the silica particle number A is not greater than the above value in the present invention. In addition, in the present invention, the silica particle number ratio B may be not greater than the above value, or the silica particle number ratio C may be not greater than the above value.

In addition, in recent years, there has been a higher demand for reducing a dimensional change of the cured object due to heat. In order to reduce a dimensional change of the cured object due to heat, there is a method in which a contained amount of silica is increased. In the present invention, even when the contained amount of silica in 100 weight % of total solid content contained in the epoxy resin material is not less than 55 weight %, if the silica particle number A is not greater than the above value, it is possible to reduce the surface roughness of the roughening-treated surface of the roughened cured material and to increase the adhesive strength between the cured object and the metal layer. Moreover, even when the contained amount of silica in 100 weight % of the total solid content contained in the epoxy resin material is not less than 55 weight %, if the silica particle number ratio B or the silica particle number ratio C is not greater than the above value, it is possible to effectively reduce the surface roughness of the roughening-treated surface of the roughened cured material and to effectively increase the adhesive strength between the cured object and the metal layer.

In addition, if the silica particle number A is not greater than the above value, when forming a metal layer on the surface of the roughened cured material and curing the roughened cured material, blistering of the metal layer becomes hard to occur, and the metal layer becomes hard to peel off from the surface of the cured object. Furthermore, also in a reflow process, blistering of the metal layer becomes hard to occur, and the metal layer becomes hard to peel off from the surface of the cured object. Moreover, if the silica particle number ratio B or the silica particle number ratio C is not greater than the above value, when forming a metal layer on the surface of the roughened cured material and curing the roughened cured material, blistering of the metal layer effectively becomes hard to occur, and the metal layer becomes further hard to peel off from the surface of the cured object. Furthermore, also in a reflow process, blistering of the metal layer effectively becomes hard to occur, and the metal layer becomes further hard to peel off from the surface of the cured object.

Examples of a method for causing the silica particle number A, the silica particle number ratio B, or the silica particle number ratio C to be not greater than the above value include a method in which a resin component and a silica that are moderately dissolved during the roughening treatment are used as the resin component and the silica contained in the epoxy resin material, a method in which, in order to dissolve a resin component and a silica, a roughening liquid that allows the resin component and the silica to be moderately dissolved is used, and the like. The resin component contains the epoxy resin and the curing agent.

When the resin component is excessively dissolved by the roughening treatment, the exposed amount of silica tends to be increased. When the resin component is excessively less dissolved by the roughening treatment, it becomes hard to form pores themselves. In addition, when the resin component is excessively dissolved, the thickness of the roughened cured material is also decreased, and it becomes hard to obtain a uniform roughened surface. Moreover, when the resin component is excessively less dissolved, it becomes hard to eliminate the silica by the roughening treatment.

When the silica is excessively less dissolved by the roughening treatment, it becomes hard to form pores themselves, and large silica is likely to remain within each pore. In addition, when the rate at which the silica is dissolved by the roughening treatment is too high, the roughening liquid infiltrates through the silica interface, and the resin component tends to be easily removed more than needs.

In addition, examples of a specific method for causing the silica particle number A, the silica particle number ratio B, or the silica particle number ratio C to be not greater than the above value include (1) a first method in which the ratio of an epoxy resin having an epoxy equivalent of 150 or higher, to 100 weight % of the total weight of the used epoxy resin, is made not less than 75 weight %, (2) a second method in which the ratio of an epoxy resin in the form of a liquid at normal temperature (23° C.) to 100 weight % of the total weight of the used epoxy resin is made not less than 40 weight %, (3) a third method in which the surface of the silica is treated so as to be hydrophobic, and the like. A method other than these first to third methods may be used.

In the first method, a functional group (a hydroxy group, an ester group, and an oxazoline ring, etc.) generated after curing is restrained from being locally concentrated, increase in water absorption rate is suppressed, the resin component becomes hard to be roughened, and thus it is possible to suppress exposure of the silica. In the second method, since the fluidity of an un-cured object (in a B stage state) is high, it is possible to ensure a certain degree of fluidity even during curing until the curing sufficiently advances. As a result, an epoxy group in the epoxy resin and a reactive group in the curing agent become easy to access each other. Thus, it is possible to increase the rate of reaction, a large amount of an unreacted group is restrained from remaining, increase in water absorption rate is suppressed, excessive roughening becomes hard to occur, and thus it is possible to suppress exposure of the silica. In the third method, it is possible to use a silica that is surface-treated with a silane coupling agent such as epoxysilane, vinylsilane, or phenylsilane in order to hydrophobize the surface of the silica. In addition, in the third method, infiltration of the roughening liquid through the interface between the resin component and the silica is suppressed, the resin component becomes hard to be roughened more than needs, and thus it is possible to suppress exposure of the silica.

In addition, when two or more types of epoxy resins having moderate solubility in the roughening liquid are used or two or more types of epoxy resins having different curabilities but high uniformity (compatibility) are used, it is also possible to control the amount of exposed silica to be small. For example, when two or more types of epoxy resins having high uniformity are used, even if the resin composition that is the epoxy resin material is stored, the resin composition becomes hard to separate. As a result, the particle number of exposed silica is decreased, and the size of each exposed portion of the silica is decreased. On the other hand, when an epoxy resin that is easily soluble in the roughening liquid is used, the thickness of the roughened cured material is decreased by the roughening treatment, and the silica is likely to remain so as to have exposed portions.

In the roughened cured material 11, the pores 11c exist on the roughening-treated first surface 11a. In each pore 11c, a residual silica 12X exists or does not exist. In the roughened cured material 11, when the roughening-treated first surface 11a is photographed with a scanning electron microscope, in a 5 μm×5 μm sized area of the roughening-treated first surface 11a in the photographed image, the number of particles of the residual silica 12X within the pores 11c appearing in the image each of which particles has a maximum length (L2 in FIG. 2(a)) of 0.3 μm or longer in the image or has a maximum length (L2 in FIG. 2(a)) (μm), in the image, that is less than 0.3 μm and is equal to or larger than two-thirds of the maximum length (L1 in FIG. 2(a)) (μm), in the image, of the pore 11c receiving the residual silica 12X (hereinafter, sometimes denoted as residual silica particle number D) is preferably not greater than 15. In this case, the surface roughness of the roughening-treated surface of the roughened cured material is effectively reduced, and the adhesive strength between the cured object and the metal layer is effectively increased.

The “residual silica particle number D” is the sum of: the number D1 of particles of the residual silica 12X within the pores 11c appearing in the image, each of which particles has a maximum length of 0.3 μm or longer in the image; and the number D2 of particles of the residual silica 12X within the pores 11c appearing in the image, each of which particles has a maximum length (μm), in the image, that is less than 0.3 μm and is equal to or larger than two-thirds of the maximum length, in the image, of the pore 11c receiving the residual silica 12X. The number D2 is the number of particles of the residual silica 12X each of which particles has a maximum length (μm), in the image, that is less than 0.3 μm and is equal to or larger than two-thirds of the maximum length (μm), in the image, of the pore 11c receiving the residual silica 12X.

From a standpoint of further reducing the surface roughness of the roughening-treated surface of the roughened cured material and further increasing the adhesive strength between the cured object and the metal layer, the residual silica particle number D is more preferably not greater than 12 and further preferably not greater than 8. In addition, in the present invention, the residual silica particle number D is not 0 and may be not less than 1. Even when the residual silica particle number D is not less than 1, if the number D is not greater than 15, it is possible to effectively reduce the surface roughness of the roughening-treated surface of the roughened cured material and to effectively increase the adhesive strength between the cured object and the metal layer.

In addition, in the roughened cured material 11, when the roughening-treated first surface 11a is photographed with a scanning electron microscope, in a 5 μm×5 μm sized area of the roughening-treated first surface 11a in the photographed image, the ratio n of the number of pores each receiving the residual silica that is the residual silica 12X within each pore 11c appearing in the image and has a maximum length (L2 in FIG. 2(a)) of 0.3 μm or longer in the image or has a maximum length (L2 in FIG. 2(a)) (μm), in the image, that is less than 0.3 μm and is equal to or larger than two-thirds of the maximum length (L1 in FIG. 2(a)) (μm), in the image, of the pore receiving the residual silica, to the total number Ne of pores 11c that appear in the image and do not receive the residual silica 12X and pores that appear in the image and receive the residual silica 12X, (hereinafter, sometimes denoted as the ratio E of the number of the pores receiving the residual silica) is preferably not greater than 20%. In this case, the surface roughness of the roughening-treated surface of the roughened cured material is effectively reduced, and the adhesive strength between the cured object and the metal layer is effectively increased. The ratio E is obtained by a formula: number n/total number Ne×100.

The “ratio E of the number of the pores receiving the residual silica” is the sum of: the ratio E1 of the number n1 of pores 11c each receiving the residual silica 12X that is the residual silica 12X within each pore 11e appearing in the image and has a maximum length in the image of 0.3 μm or longer, to the total number Ne of the pores 11c that appear in the image and do not receive the residual silica 12X and the pores 11c that appear in the image and receive the residual silica 12X; and the ratio E2 of the number n2 of pores 11c each receiving the residual silica 12X that is the residual silica 12X within each pore 11c appearing in the image and has a maximum length (μm), in the image, that is less than 0.3 μm and is equal to or larger than two-thirds of the maximum length (μm), in the image, of the pore 11c receiving the residual silica 12X, to the total number Ne of the pores 11c that appear in the image and do not receive the residual silica 12X and the pores 11c that appear in the image and receive the residual silica 12X. The ratio E1 (%) is obtained by a formula: number n1/total number Ne×100. The ratio E2 (%) is obtained by a formula: number n2/total number Ne×100.

From a standpoint of further reducing the surface roughness of the roughening-treated surface of the roughened cured material and further increasing the adhesive strength between the cured object and the metal layer, the ratio E of the number of the pores receiving the residual silica is more preferably not greater than 15% and further preferably not greater than 10%. In addition, in the present invention, the ratio E of the number of the pores receiving the residual silica may not be 0%, may exceed 0%, or may exceed 1%. Even when the ratio E of the number of the pores receiving the residual silica exceeds 0% or exceeds 1%, if the ratio E is not greater than 20%, it is possible to effectively reduce the surface roughness of the roughening-treated surface of the roughened cured material and to effectively increase the adhesive strength between the cured object and the metal layer.

In addition, in the roughened cured material 11, when the roughening-treated first surface 11a is photographed with a scanning electron microscope, in a 5 μm×5 μm sized area of the roughening-treated first surface 11a in the photographed image, the ratio n of the number of pores each receiving the residual silica that is the residual silica 12X within each pore 11c appearing in the image and has a maximum length (L2 in FIG. 2(a)) of 0.3 μm or longer in the image or has a maximum length (L2 in FIG. 2(a)) (μm), in the image, that is less than 0.3 μm and is equal to or larger than two-thirds of the maximum length (L1 in FIG. 2(a)) (μm), in the image, of the pore receiving the residual silica, to the number Nf of pores that appear in the image and receive the residual silica 12X, (hereinafter, sometimes denoted as the ratio F of the number of the pores receiving the residual silica) is preferably not greater than 50%. In this case, the surface roughness of the roughening-treated surface of the roughened cured material is effectively reduced and the adhesive strength between the cured object and the metal layer is effectively increased. The ratio F is obtained by a formula: number n/total number Nf×100.

The “ratio F of the number of the pores receiving the residual silica” is the sum of: the ratio F1 of the number n1 of pores 11c each receiving the residual silica 12X that is the residual silica 12X within each pore 11c appearing in the image and has a maximum length of 0.3 μm or longer in the image, to the number Nf of the pores 11c that appear in the image and receive the residual silica 12X; and the ratio F2 of the number n2 of pores 11c each receiving the residual silica 12X that is the residual silica 12X within each pore 11c appearing in the image and has a maximum length (μm), in the image, that is less than 0.3 μm and is equal to or larger than two-thirds of the maximum length (μm), in the image, of the pore 11c receiving the residual silica 12X, to the number Nf of the pores 11c that appear in the image and receive the residual silica 12X. The ratio F1 (%) is obtained by a formula: number n1/total number Nf×100. The ratio F2 (%) is obtained by a formula: number n2/total number Nf×100.

From a standpoint of further reducing the surface roughness of the roughening-treated surface of the roughened cured material and further increasing the adhesive strength between the cured object and the metal layer, the ratio F of the number of the pores receiving the residual silica is more preferably not greater than 40% and further preferably not greater than 30%. In addition, in the present invention, the ratio F of the number of the pores receiving the residual silica may not be 0%, may exceed 0%, or may exceed 1%. Even when ratio F of the number of the pores receiving the residual silica exceeds 0% or exceeds 1%, if the ratio F is not greater than 50%, it is possible to effectively reduce the surface roughness of the roughening-treated surface of the roughened cured material and to effectively increase the adhesive strength between the cured object and the metal layer.

In each pore receiving the residual silica, the roughening liquid enters around the residual silica, and a defect such as a plating defect is likely to occur. In addition, the plating solution is likely to remain around the residual silica. When the residual silica particle number D, the ratio E of the pores receiving the residual silica, or the ratio F of the number of the pores receiving the residual silica is not greater than the above value, it is possible to form minute pores on the roughening-treated surface of the roughened cured material, and thus it is possible to effectively reduce the surface roughness of the roughening-treated surface. As a result, the adhesive strength between the cured object and the metal layer is also increased. In addition, it is possible to prevent decrease in insulation properties that is caused by the roughening liquid remaining between the silica and the resin component. In the present invention, in order to effectively reduce the surface roughness of the roughening-treated surface of the roughened cured material and further to effectively increase the adhesive strength between the cured object and the metal layer, the residual silica particle number D may be not greater than the above value, the ratio E of the pores receiving the residual silica may be not greater than the above value, or the ratio F of the pores receiving the residual silica may be not greater than the above value.

In the present invention, even when the contained amount of silica in 100 weight % of the total solid content contained in the epoxy resin material is not less than 55 weight %, if the residual silica particle number D, the ratio E of the pores receiving the residual silica, or the ratio F of the pores receiving the residual silica is not greater than the above value, it is possible to effectively reduce the surface roughness of the roughening-treated surface of the roughened cured material and to effectively increase the adhesive strength between the cured object and the metal layer.

In addition, if the residual silica particle number D, the ratio E of the pores receiving the residual silica, or the ratio F of the pores receiving the residual silica is not greater than the above value, when forming a metal layer on the surface of the roughened cured material and curing the roughened cured material, blistering of the metal layer effectively becomes hard to occur, and the metal layer becomes further hard to peel off from the surface of the cured object. Furthermore, also in a reflow process, blistering of the metal layer effectively becomes hard to occur, and the metal layer becomes further hard to peel off from the surface of the cured object. As a result, the adhesive strength between the cured object and the metal layer is effectively increased.

Examples of a method for causing the residual silica particle number D, the ratio E of the pores receiving the residual silica, or the ratio F of the pores receiving the residual silica to be not greater than the above value include a method in which a resin component and a silica that are moderately dissolved during the roughening treatment are used as the resin component and the silica contained in the epoxy resin material, a method in which, in order to dissolve a resin component and a silica, a roughening liquid that allows the resin component and the silica to be moderately dissolved is used, and the like. The resin component contains the epoxy resin and the curing agent.

When the resin component is excessively dissolved by the roughening treatment, it is necessary to shorten the roughening time period in order to ensure a finely roughened surface, and thus the amount of remaining silica is increased. When the resin component is excessively less dissolved by the roughening treatment, it becomes hard to form pores themselves. In addition, when the resin component is excessively dissolved, the thickness of the roughened cured material is also decreased, and it becomes hard to obtain a uniform roughened surface. Moreover, when the resin component is excessively less dissolved, it becomes hard to eliminate the silica by the roughening treatment.

When the silica is excessively less dissolved by the roughening treatment, it becomes hard to form pores themselves, and large silica is likely to remain within each pore. In addition, when the rate at which the silica is dissolved by the roughening treatment is too high, the roughening liquid infiltrates through the silica interface, and the resin component tends to be easily removed more than needs.

In addition, examples of a specific method for causing the residual silica particle number D, the ratio E of the pores receiving the residual silica, or the ratio F of the pores receiving the residual silica to be not greater than the above value include (1) Method 1 in which the ratio of an epoxy resin having an epoxy equivalent of 150 or higher, to 100 weight % of the total weight of the used epoxy resin, is made not less than 75 weight %, (2) Method 2 in which the ratio of an epoxy resin in the form of a liquid at normal temperature (23° C.) to 100 weight % of the total weight of the used epoxy resin is made not less than 40 weight %, (3) Method 3 in which the surface of the silica is treated so as to be hydrophobic, and the like. A method other than these Methods 1 to 3 may be used.

In Method 1, a functional group (a hydroxy group, an ester group, and an oxazoline ring, etc.) generated after curing is restrained from being locally concentrated, increase in water absorption rate is suppressed, the resin component becomes hard to be roughened, and it is possible to ensure a long roughening time period. Thus, it is possible to restrain the silica from being bonded to the resin within each pore and remaining therein. In Method 2, since the fluidity of an un-cured object (in a B stage state) is high, it is possible to ensure a certain degree of fluidity even during curing until the curing sufficiently advances. As a result, an epoxy group in the epoxy resin and a reactive group in the curing agent become easy to access each other. Thus, it is possible to increase the rate of reaction, a large amount of an unreacted group is restrained from remaining, increase in water absorption rate is suppressed, excessive roughening becomes hard to occur, and it is possible to ensure a long roughening time period. Thus, it is possible to restrain the silica from being bonded to the resin within each pore and remaining therein. In Method 3, it is possible to use a silica that is surface-treated with a silane coupling agent such as epoxysilane, vinylsilane, or phenylsilane in order to hydrophobize the surface of the silica. In addition, in the third method, infiltration of the roughening liquid through the interface between the resin component and the silica is suppressed, the resin component becomes hard to be roughened more than needs, and it is possible to ensure a long roughening time period. Thus, it is possible to restrain the silica from being bonded to the resin within each pore and remaining therein.

In the following, details of each component contained in the epoxy resin material will be described first.

(Epoxy Resin Material)

[Epoxy Resin]

There is no particular limitation in the epoxy resin contained in the epoxy resin material. It is possible to use a hitherto known epoxy resin as the epoxy resin. The epoxy resin refers to an organic compound including at least one epoxy group. With regard to the epoxy resin, a single type may be used by itself, or a combination of two or more types may be used.

Examples of the epoxy resin include bisphenol A type epoxy resins, bisphenol F type epoxy resins, bisphenol S type epoxy resins, phenol novolac type epoxy resins, biphenyl novolac type epoxy resins, biphenol type epoxy resins, naphthalene type epoxy resins, fluorene type epoxy resins, phenol aralkyl type epoxy resins, naphthol aralkyl type epoxy resins, dicyclopentadiene type epoxy resins, anthracene type epoxy resins, epoxy resins having an adamantane backbone, epoxy resins having a tricyclodecane backbone, epoxy resins having a triazine nucleus as a backbone, and the like.

From a standpoint of further reducing the surface roughness of the roughening-treated surface of the roughened cured material and further increasing the adhesive strength between the cured object and the metal layer, the epoxy resin is preferably a bisphenol A type epoxy resin, a bisphenol F type epoxy resin, a biphenyl novolac type epoxy resin, a biphenol type epoxy resin, a phenol aralkyl type epoxy resin, a naphthol aralkyl type epoxy resin, or a dicyclopentadiene type epoxy resin.

From a standpoint of further reducing the surface roughness of the roughening-treated surface of the roughened cured material, further increasing the adhesive strength between the cured object and the metal layer, and further providing further excellent insulation reliability by the cured object, the epoxy resin is particularly preferably a biphenyl novolac type epoxy resin, a phenol aralkyl type epoxy resin, a naphthol aralkyl type epoxy resin, or a dicyclopentadiene type epoxy resin.

From a standpoint of further reducing the surface roughness of the roughening-treated surface of the roughened cured material and further increasing the adhesive strength between the cured object and the metal layer, the epoxy equivalent of the epoxy resin is preferably equal to or higher than 90, and more preferably equal to or higher than 100; and preferably equal to or lower than 1000, and more preferably equal to or lower than 800.

The weight average molecular weight of the epoxy resin is preferably equal to or less than 1000. In this case, it is possible to increase the contained amount of silica in the epoxy resin material. Furthermore, even when the contained amount of silica is large, it is possible to obtain a resin composition which is an epoxy resin material having high fluidity.

[Curing Agent]

There is no particular limitation in the curing agent contained in the epoxy resin material. It is possible to use a hitherto known curing agent as the curing agent. With regard to the curing agent, a single type may be used by itself, or a combination of two or more types may be used.

Examples of the curing agent include cyanate ester resins (cyanate ester curing agents), phenolic compounds (phenol curing agent), amine compounds (amine curing agents), thiol compounds (thiol curing agents), imidazole compounds, phosphine compounds, acid anhydrides, active ester compounds, and dicyandiamide, etc. Among those, from a standpoint of obtaining a cured object that has a further small dimensional change derived by heat, the curing agent is preferably a cyanate ester resin or a phenolic compound. As the curing agent, a cyanate ester resin is preferable, and a phenolic compound is also preferable. The curing agent preferably has a functional group capable of reacting with an epoxy group in the epoxy resin.

From a standpoint of further reducing the surface roughness of the roughening-treated surface of the roughened cured material and further increasing the adhesive strength between the cured object and the metal layer, the curing agent is preferably a cyanate ester resin, a phenolic compound, or an active ester compound. Furthermore, from a standpoint of providing further excellent insulation reliability by the curing agent, the curing agent is more preferably a cyanate ester resin.

By using the above described cyanate ester resin, it is possible to obtain excellent handleability for a B stage film having a large contained amount of silica, and to further raise the glass transition temperature of the cured object. There is no particular limitation in the cyanate ester resin. It is possible to use a hitherto known cyanate ester resin as the cyanate ester resin. With regard to the cyanate ester resin, a single type may be used by itself, or a combination of two or more types may be used.

Examples of the cyanate ester resin include novolac type cyanate resins and bisphenol type cyanate resins, etc. Examples of the bisphenol type cyanate resins include bisphenol A type cyanate resins, bisphenol E type cyanate resins, and tetramethyl bisphenol F type cyanate resins, etc.

Examples of commercially available products of the cyanate ester resin include phenol novolac type cyanate resins (“PT-30” and “PT-60” manufactured by Lanza Japan Ltd.), prepolymers obtained by modifying bisphenol A dicyanate to have a triazine structure so as to be a trimer (“BA230,” “BA200,” and “BA3000” manufactured by Lonza Japan Ltd.), etc.

By using the above described phenolic compound, it is possible to further increase the adhesive strength between the cured object and the metal layer. In addition, when the phenolic compound is used, for example, by conducting a blacking process or a Cz process on a surface of copper disposed on the surface of the cured object, it is possible to further enhance adhesivity between the cured object and copper.

There is no particular limitation in the phenolic compound. It is possible to use a hitherto known phenolic compound as the phenolic compound. With regard to the phenolic compound, a single type may be used by itself, or a combination of two or more types may be used.

Examples of the phenolic compound include novolac type phenols, biphenol type phenols, naphthalene type phenols, dicyclopentadiene type phenols, aralkyl type phenols, and dicyclopentadiene type phenols, etc.

Examples of commercially available products of the phenolic compound include novolac type phenols (“TD-2091” manufactured by DIC Corp.), biphenyl novolac type phenols (“MEH-7851” manufactured by Meiwa Plastic Industries, Ltd.), and aralkyl type phenolic compounds (“MEH-7800” manufactured by Meiwa Plastic Industries, Ltd), etc.

From a standpoint of further reducing the surface roughness of the roughening-treated surface of the roughened cured material and further increasing the adhesive strength between the cured object and the metal layer, the phenolic compound is preferably a biphenyl novolac type phenol or an aralkyl type phenolic compound.

There is no particular limitation in the above described active ester compound. Examples of commercially available products of the above described active ester compound include “HPC-8000” manufactured by DIC Corp., etc.

From a standpoint of further reducing the surface roughness of the roughening-treated surface of the roughened cured material, further increasing the adhesive strength between the cured object and the metal layer, and providing excellent insulation reliability by the curing agent, an equivalent of the curing agent is preferably equal to or lower than 250. For example, the equivalent of the curing agent represents a cyanate ester group equivalent when the curing agent is a cyanate ester resin, represents a phenolic hydroxyl group equivalent when the curing agent is a phenolic compound, and represents an active ester group equivalent when the curing agent is an active ester compound.

The weight average molecular weight of the curing agent is preferably equal to or lower than 1000. In this case, it is possible to increase the contained amount of silica in the epoxy resin material, and even when the contained amount of silica is large, it is possible to obtain a resin composition which is an epoxy resin material having high fluidity.

In 100 weight % of total solid content excluding the silica contained in the epoxy resin material (hereinafter, sometimes abbreviated as total solid content B), the contained amount of the total of the epoxy resin and the curing agent is preferably equal to or greater than 75 weight %, and more preferably equal to or greater than 80 weight %; and equal to or less than 100 weight %, preferably equal to or less than 99 weight %, and more preferably equal to or less than 97 weight %.

When the contained amount of the total of the epoxy resin and the curing agent is not lower than the above described lower limit but not higher than the above described upper limit; it becomes possible to obtain a further excellent cured object, obtain an excellent existing status of the silica due to an ability of adjusting the melt viscosity, and prevent the B stage film from becoming wet and spreading into unintended regions during the curing process. In addition, it is possible to further suppress dimensional changes of the cured object due to heat. Furthermore, when the contained amount of the total of the epoxy resin and the curing agent is less than the lower limit, it becomes difficult to embed the resin composition or the B stage film in holes or concavities/convexities on a circuit board, and the dispersion state of the silica tends to deteriorate. In addition, when the contained amount of the total of the epoxy resin and the curing agent is higher than the upper limit, the melt viscosity becomes too low, and the B stage film tends to easily become wet and spread into unintended regions during the curing process. “Total solid content B” refers to a total of the epoxy resin, the curing agent, and other solid contents that are blended if necessary. The silica is not included in the total solid content B. “Solid content” refers to nonvolatile components, and components that do not become volatilized at the time of molding or heating.

There is no particular limitation in the blend ratio of the epoxy resin and the curing agent. The blend ratio of the epoxy resin and the curing agent is determined as appropriate in accordance with the types of the epoxy resin and the curing agent, etc.

[Silica]

The epoxy resin material contains the silica.

The mean particle diameter of the silica contained in the epoxy resin material is not small than 0.2 μm but not larger than 1.2 μm. The mean particle diameter of the silica is preferably not larger than 1 μm. As the mean particle diameter of the silica, a value of median diameter (d50) representing 50% is used. It is possible to measure the mean particle diameter by using a particle-size-distribution measuring device that employs a laser diffraction scattering method.

The silica is preferably surface-treated, and more preferably surface-treated with a coupling agent. As a result, it becomes possible to further reduce the surface roughness of the roughening-treated surface of the roughened cured material, further increase the adhesive strength between the cured object and the metal layer, and provide further excellent inter-wiring insulation reliability and interlayer insulation reliability.

Examples of the coupling agent include silane coupling agents, titanate coupling agents, and aluminium coupling agents, etc. The coupling agent used for surface treatment described above is preferably epoxysilane, aminosilane, vinylsilane, mercaptosilane, sulfur silane, (meth)acrylic silane, isocyanate silane, or ureido silane, etc.

There is no particular limitation in the contained amount of the silica. In 100 weight % of the total solid content (hereinafter, sometimes abbreviated as total solid content A) contained in the epoxy resin material, the contained amount of the silica is preferably equal to or greater than 30 weight %, more preferably equal to or greater than 40 weight %, further preferably equal to or greater than 50 weight %, particularly preferably equal to or greater than 55 weight %; and preferably equal to or less than 85 weight % and more preferably equal to or less than 80 weight %. In 100 weight % of the total solid content A, the contained amount of the silica is particularly preferably equal to or greater than 55 weight % and particularly preferably equal to or less than 80 weight %. When the contained amount of the silica is not lower than the above described lower limit but not higher than the above described upper limit, the coefficient of linear expansion of the cured object is decreased. “Total solid content A” refers to the sum of the epoxy resin, the curing agent, the silica, and the solid content that is blended in if necessary. “Solid content” refers to nonvolatile components, and components that do not become volatilized at the time of molding or heating.

[Details of Other Components and Resin Composition]

The epoxy resin material may contain a curing accelerator if necessary. By using the curing accelerator, it is possible to further increase the curing rate. When the epoxy resin material is immediately cured, it becomes possible to homogenize a crosslink structure of the cured object, reduce the number of unreacted functional groups, and, as a result, increase crosslink density. There is no particular limitation in the curing accelerator. It is possible to use a hitherto known curing accelerator as the curing accelerator. With regard to the curing accelerator, a single type may be used by itself, or a combination of two or more types may be used.

Examples of the curing accelerator include imidazole compounds, phosphorus compounds, amine compounds, and organometallic compounds, etc.

Examples of the imidazole compound include, 2-undecylimidazole, 2-heptadecylimidazole, 2-methylimidazole, 2-ethyl-4-methyl imidazole, 2-phenylimidazole, 2-phenyl-4-methylimidazole, 1-benzyl-2-methylimidazole, 1-benzyl-2-phenylimidazole, 1,2-dimethylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-cyanoethyl-2-undecyl imidazolium trimellitate, 1-cyanoethyl-2-phenyl imidazolium trimellitate, 2,4-diamino-6-[2′-methyl imidazolyl-(1′)]-ethyl-s-triazine, 2,4-diamino-6-[2′-undecyl imidazolyl-(1′)]-ethyl-s-triazine, 2,4-diamino-6-[2′-ethyl-4′-methyl imidazolyl-(1′)]-ethyl-s-triazine, 2,4-diamino-6-[2′-methyl imidazolyl-(1′)]-ethyl-s-triazine isocyanuric acid adducts, 2-phenyl imidazole isocyanuric acid adducts, 2-methyl imidazole isocyanuric acid adducts, 2-phenyl-4,5-dihydroxymethylimidazole, and 2-phenyl-4-methyl-5-dihydroxymethylimidazole, etc.

Examples of the phosphorus compound include triphenyl phosphine, etc.

Examples of the amine compound include diethylamine, triethylamine, diethylene tetramine, triethylenetetramine, and 4,4-dimethylamino pyridine, etc.

Examples of the organometallic compound include zinc naphthenate, cobalt naphthenate, tin octylate, cobalt octylate, bis acetylacetonato cobalt (II), and tris acetylacetonato cobalt (III), etc.

From a standpoint of increasing the insulation reliability of the cured object, the curing accelerator is particularly preferably an imidazole compound.

There is no particular limitation in the contained amount of the curing accelerator. From a standpoint of efficiently curing the epoxy resin material, in 100 weight % of the total solid content B, the contained amount of the curing accelerator is preferably equal to or greater than 0.01 weight % and preferably equal to or less than 3 weight %. It should be noted that the curing accelerator is included in the total solid content B.

The epoxy resin material may contain a thermoplastic resin. By using a thermoplastic resin, it becomes possible to increase followability of the epoxy resin material to concavities and convexities of circuits, further reduce the surface roughness of the roughening-treated surface of the roughened cured material, and further homogenize the roughness of the roughening-treated surface.

Examples of the thermoplastic resin include phenoxy resins and polyvinyl acetal resins etc. From a standpoint of causing the silica to excellently exist, further reducing the surface roughness of the roughening-treated surface of the roughened cured material, and further increasing the adhesive strength between the cured object and the metal layer; the thermoplastic resin is preferably a phenoxy resin.

Examples of the phenoxy resin include phenoxy resins having backbones such as bisphenol A type backbones, bisphenol F type backbones, bisphenol S type backbones, biphenyl backbones, novolac backbones, and naphthalene backbones.

Since it is possible to increase the adhesive strength between the cured object and the metal layer when a plating process for forming a metal layer is conducted after the roughening treatment of the surface of the preliminary-cured material, the phenoxy resin preferably has a biphenyl backbone, and more preferably has a biphenol backbone.

Specific examples of the phenoxy resin include, for example, “YP50”, “YP55”, and “YP70” manufactured by Tohto Kasei Co., Ltd., and “1256B40”, “4250”, “4256H40”, “4275”, “YX6954BH30”, “YX8100BH30”, “YL7600DMACH25”, and “YL7213BH30” manufactured by Mitsubishi Chemical Corp.

The weight average molecular weight of the phenoxy resin is preferably equal to or higher than 5000 and preferably equal to or lower than 100000.

There is no particular limitation in the contained amount of the thermoplastic resin. In 100 weight % of the total solid content B, the contained amount of the thermoplastic resin (when the thermoplastic resin is a phenoxy resin, the contained amount of the phenoxy resin) is preferably equal to or greater than 0.1 weight %, more preferably equal to or greater than 0.5 weight %, and further preferably equal to or greater than 1 weight %, and preferably equal to or less than 40 weight %, more preferably equal to or less than 30 weight %, further preferably equal to or less than 20 weight %, and particularly preferably equal to or less than 15 weight %. When the contained amount of the thermoplastic resin is not lower than the above described lower limit but not higher than the above described upper limit, a dimensional change of the cured object due to heat is further reduced. Furthermore, when the contained amount of the thermoplastic resin is not higher than the above described upper limit, embeddability of the epoxy resin material with respect to holes or concavities/convexities of circuit boards becomes excellent. It should be noted that the thermoplastic resin is included in the total solid content B.

For the purpose of improving shock resistance, heat resistance, resin compatibility, and workability, etc.; a coupling agent, a coloring agent, an antioxidant, an ultraviolet-ray-degradation inhibitor, a defoaming agent, a thickening agent, a thixotropic agent, and other resins other than the resins described above may be added to the epoxy resin material.

Examples of the coupling agent include silane coupling agents, titanium coupling agents, and aluminium coupling agents, etc. Examples of the silane coupling agent include vinylsilane, aminosilane, imidazole silane, and epoxysilane, etc.

There is no particular limitation in the contained amount of the coupling agent. In 100 weight % of the total solid content B, the contained amount of the coupling agent is preferably equal to or greater than 0.01 weight % but equal to or less than 5 weight %. It should be noted that the coupling agent is included in the total solid content B.

Examples of the other resins described above include polyphenylene ether resins, divinylbenzyl ether resins, polyarylate resins, diallyl phthalate resins, polyimide resins, benzoxazine resins, benzoxazole resins, bismaleimide resins, and acrylate resins, etc.

The epoxy resin material may include a solvent. Examples of the solvent include acetone, methanol, ethanol, butanol, 2-propanol, 2-methoxyethanol, 2-ethoxyethanol, 1-methoxy-2-propanol, 2-acetoxy-1-methoxy propane, toluene, xylene, methyl ethyl ketone, N,N-dimethylformamide, methyl isobutyl ketone, N-methyl-pyrrolidone, n-hexane, cyclohexane, cyclohexanone, and naphtha which is a mixture, etc. With regard to the solvent, a single type may be used by itself, or a combination of two or more types may be used.

It is possible to use, as a varnish, a resin composition containing a solvent. It is possible to calibrate the viscosity of the varnish by adjusting the contained amount of solvent in accordance with the use application. In the epoxy resin material, with respect to 100 parts by weight of the total solid content A, the contained amount of the solvent is preferably equal to or greater than 10 parts by weight and preferably equal to or less than 1000 parts by weight.

(Details of B Stage Film, Lamination Film, Preliminary-Cured material, Roughened Cured material, and Laminated Body)

The epoxy resin material may be a resin composition, or a B stage film resulting from molding the resin composition into a film form. It is possible to obtain the B stage film by molding the resin composition into a film form.

Examples of the method for molding the resin composition into a film include: an extrusion method of fusing, kneading, and extruding the resin composition using an extruder, and then molding the resin composition into a film form using a T-die or a circular die, etc.; a mold casting method of dissolving or dispersing the resin composition in a solvent such as an organic solvent or the like, and then casting and molding an obtained mixture into a film form; and hitherto known other film molding methods, etc. In particular, an extrusion method or a mold casting method is preferable since it is possible to obtain a thinner product. The film includes a sheet.

It is possible to obtain the B stage film by molding the resin composition into a film form, and heating and drying the resin composition at, for example, 90 to 200° C. for 10 to 180 minutes at a degree that does not cause curing to excessively advance due to the heat.

A film form resin composition that can be obtained by the drying step as described above is referred to as a B stage film.

The B stage film is a semi-cured object in a semi-cured state. The semi-cured object is not completely cured, and it is possible to further advance curing.

The resin composition is suitably used for forming a lamination film including a base material and a B stage film laminated on one of the surfaces of the base material. The B stage film for the lamination film is formed using the resin composition.

Examples of the base material for the lamination film include polyester resin films such as polyethylene terephthalate films and polybutylene terephthalate films, olefin resin films such as polyethylene films and polypropylene films, polyimide resin films, and metallic foils such as copper foils and aluminium foils, etc. A release-process may be conducted on the surface of the base material if necessary.

When the epoxy resin material is used as an insulation layer of a circuit, the thickness of the layer formed by the epoxy resin material is preferably equal to or larger than the thickness of a conductor layer forming the circuit. The thickness of the layer formed by the epoxy resin material is preferably not smaller than 5 μm and preferably not larger than 200 μm.

Preferably, the epoxy resin material is a B stage film, and a preliminary-cured material is obtained by layering the B stage film on the lamination target object through lamination, and then advancing curing of the B stage film.

There is no particular limitation in the lamination method for laminating the B stage film, and it is possible to use a method known in the art. For example, the B stage film is laminated on a circuit board, and, preferably, the lamination film is laminated from the B stage film side, and pressure is applied using a pressurization type laminator. At this moment, heat may be applied or may not be applied. Next, heat and pressure are applied to the lamination target object and the B stage film or lamination film, using a parallel plate press type heat pressing machine. A preliminary-cured material may be formed through preliminary-curing of the B stage film by applying heat and pressure. There are no particular limitations in the temperature when applying heat and in the pressure when applying pressure, and it is possible to change the temperature and the pressure as appropriate.

A more specific lamination method is, for example, laminating the B stage film on the circuit board or laminating the lamination film on the lamination target object from the B stage film side, by, using a roll laminator, applying a pressure of 1 to 6 MPa at a roll temperature of 20 to 200° C. with a condition of a roll diameter of 60 mm and a speed of 0.1 to 10 m/minute in roll circumferential speed.

After laminating the B stage film or the lamination film on the lamination target object, a heat treatment is preferably conducted for 20 to 180 minutes at 160 to 200° C. By the heat treatment, the B stage film is preliminary-cured, whereby it is possible to obtain a preliminary-cured material. The base material of the lamination film may be removed before forming the preliminary-cured material, or may be removed after forming the preliminary-cured material. It is possible to form minute concavities and convexities on the surface of the roughened cured material by conducting the roughening treatment after lamination with the above described conditions.

If necessary, smoothness of the surface of the preliminary-cured material may be enhanced using a parallel plate heat pressing machine after the roll lamination. For example, by using the parallel plate heat pressing machine, heat and pressure may be applied using a 1 mm-thick stainless steel plate to a lamination product of the circuit board and the B stage film, or the lamination film.

It should be noted that, it is possible to use commercially available devices as a pressurization type laminator such as a heating-pressurization type roll laminator, and as a pressing machine such as a parallel plate heat pressing machine. The lamination by the roll laminator is preferably conducted in a vacuum state. It is possible to appropriately select a material for a roll of the roll laminator from rubber rolls having a soft surface and metal rolls having a hard surface. A material for a plate of the parallel plate heat pressing machine is a metal that is hard.

A film having a release function, such as aluminium foils, copper foils, polyester resin films, and fluororesin films, may be used between the roll of the roll laminator, and the lamination target object, the B stage film, or the lamination film, or between the plate of the parallel plate heat pressing machine, and the lamination target object, the B stage film, or the lamination film.

For the purpose of increasing adhesivity between the circuit board, and the B stage film or the lamination film, a material having flexibility such as a rubber sheet may be used.

Preferably, the step of forming the preliminary-cured material is a step of laminating the lamination film on the circuit board from the B stage film side, applying pressure using the roll laminator, and then applying heat and pressure using the parallel plate press type heat pressing machine to form the preliminary-cured material. In addition, preferably, the step of forming the preliminary-cured material is a step of laminating the lamination film on the lamination target object from the B stage film side, applying pressure using the roll laminator, and then applying heat and pressure using the parallel plate press type heat pressing machine to form the preliminary-cured material; wherein, the base material is removed preferably after applying pressure using the roll laminator but before applying heat and pressure using the parallel plate press type heat pressing machine, or preferably after applying pressure using the roll laminator and after applying heat and pressure using the parallel plate press type heat pressing machine.

The roughened cured material according to the present invention is obtained by conducting a roughening treatment on the first surface of the preliminary-cured material. In order to form minute concavities and convexities on the surface of the preliminary-cured material, a swelling treatment is preferably conducted on the preliminary-cured material before conducting the roughening treatment for the roughened cured material. For the preliminary-cured material, a swelling treatment is preferably conducted after the preliminary-curing but before the roughening treatment. However, the swelling treatment does not necessarily have to be conducted on the preliminary-cured material.

A laminated body according to the present invention includes a cured object resulting from curing of the roughened cured material; and a metal layer laminated on the roughening-treated surface of the cured object. The adhesive strength between the cured object and the metal layer is preferably not less than 3.9 N/cm². The metal layer is preferably a copper layer, and more preferably a copper plating layer.

(Printed Wiring Board)

The epoxy resin material is suitably used for forming an insulation layer in a printed wiring board.

The printed wiring board is obtained by, for example, using the B stage film formed by the resin composition, and molding the B stage film through application of heat and pressure.

It is possible to laminate a metallic foil on one surface or both surfaces of the B stage film. There is no particular limitation in the method for laminating the B stage film and the metallic foil, and it is possible to use a method known in the art. For example, it is possible to laminate the B stage film on the metallic foil by using a device such as a parallel plate pressing machine or a roll laminator and applying pressure with or without applying heat.

(Copper-Laid Laminated Plate and Multilayer Substrate)

The epoxy resin material is suitably used for obtaining a copper-laid laminated plate. One example of the copper-laid laminated plate is a copper-laid laminated plate including a copper foil, and a B stage film laminated on one surface of the copper foil. The B stage film of the copper-laid laminated plate is formed by the epoxy resin material. By preliminary-curing the B stage film, it is possible to obtain the copper-laid laminated plate including the preliminary-cured material.

There is no particular limitation in the thickness of the copper foil of the copper-laid laminated plate. The thickness of the copper foil is preferably within a range from 1 to 50 μm. Furthermore, in order to increase the adhesive strength between the copper foil and the cured object resulting from curing the epoxy resin material, the surface of the copper foil preferably has minute concavities and convexities. There is no particular limitation in the formation method of the concavities and convexities. Examples of the formation method of the concavities and convexities include a formation method by a process using a chemical known in the art, etc.

In addition, the preliminary-cured material is suitably used for obtaining a multilayer substrate. One example of the multilayer substrate is a multilayer substrate including a circuit board and a cured object layer laminated on one surface of the circuit board. The cured object layer of the multilayer substrate is formed by conducting a roughening treatment on the preliminary-cured material and then curing the roughened cured material. The cured object layer is preferably laminated on the surface on which circuits are disposed on the circuit board. One portion of the cured object layer is preferably embedded between the circuits.

In the multilayer substrate, more preferably, a roughening treatment is conducted on a surface of the cured object layer opposite to the surface on which the circuit board is laminated. There is no particular limitation in the roughening treatment method, and it is possible to use a hitherto known roughening treatment method. A swelling treatment may be conducted on the surface of the cured object layer before the roughening treatment.

In addition, the multilayer substrate preferably includes a copper plating layer laminated on the roughening-treated surface of the cured object layer.

Furthermore, other examples of the multilayer substrate include a multilayer substrate including: a circuit board; a cured object layer laminated on the surface of the circuit board; and a copper foil laminated on a surface of the cured object layer opposite to the surface on which the circuit board is laminated. The copper foil and the cured object layer are preferably formed by using a copper-laid laminated plate including the copper foil and a B stage film laminated on one of the surfaces of the copper foil, and preliminary-curing, roughening, and curing the B stage film. Furthermore, an etching process is preferably conducted on the copper foil to form a copper circuit.

Other examples of the multilayer substrate include a multilayer substrate including a circuit board and multiple cured object layers laminated on the surface of the circuit board. At least one layer of the multiple layers of the cured object layer is formed by the preliminary-cured material. The multilayer substrate preferably further includes a circuit laminated on at least one of the surfaces of the cured object layer formed by curing the epoxy resin material.

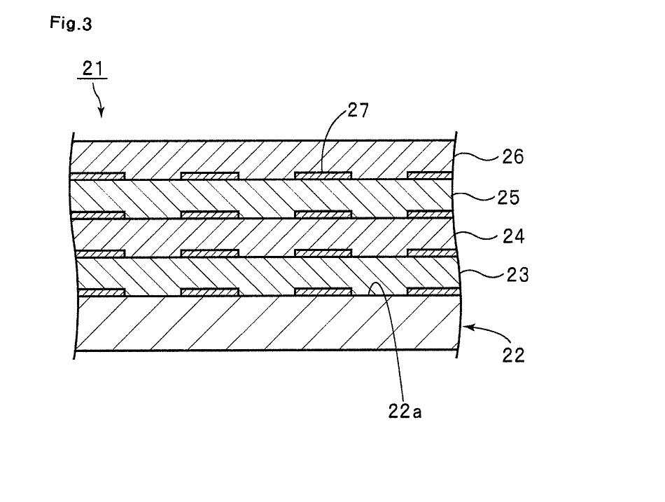

FIG. 3 is a partially cutaway cross-sectional front view schematically showing a multilayer substrate using a roughened cured material according to one embodiment of the present invention.

In a multilayer substrate 21 shown in FIG. 3, multiple layers of cured object layers 23 to 26 are laminated on an upper surface 22a of a circuit board 22. The cured object layers 23 to 26 are insulation layers. Metal layers 27 are formed on one region of the upper surface 22a of the circuit board 22. Of the multiple layers of the cured object layers 23 to 26, the metal layers 27 are formed on one region of the upper surfaces of the cured object layers 23 to 25 excluding the cured object layer 26 located on an outer side surface opposite of the circuit board 22 side. The metal layers 27 are circuits. The metal layers 27 are arranged between the circuit board 22 and the cured object layer 23, and in each interlayer of the laminated cured object layers 23 to 26. A metal layer 27 located below and a metal layer 27 located above are connected to each other by at least one of a via-hole connection and a through-hole connection not shown.

In the multilayer substrate 21, each of the cured object layers 23 to 26 is formed from the above-described roughened cured material. It should be noted that, in FIG. 3, for convenience of illustration, diagrammatic representation of silica in the cured object layers 23 to 26 and pores resulting from elimination of the silica is omitted. In the present embodiment, since roughening treatment is conducted on the surfaces of the cured object layers 23 to 26, minute pores, which are not diagrammatically represented, are formed on the surfaces of the cured object layers 23 to 26. In addition, the metal layers 27 extend inside the minute pores. Moreover, in the multilayer substrate 21, it is possible to reduce a width direction size (L) of the metal layers 27 and a width direction size (S) of a portion on which the metal layers 27 are not formed. Additionally in the multilayer substrate 21, excellent insulation reliability is provided between an upper metal layer and a lower metal layer that are not connected by the via-hole connection and the through-hole connection that are not shown.

(Swelling Treatment and Roughening Treatment)

As a method for the swelling treatment, for example, a method of treating the preliminary-cured material using, e.g., an organic solvent dispersed solution or an aqueous solution of a compound whose main component is ethylene glycol is used. A swelling liquid used in the swelling treatment generally contains an alkali as a pH adjuster etc. The swelling liquid preferably contains sodium hydroxide. Specifically, for example, the swelling treatment is conducted using a 40 weight % ethylene glycol solution etc., and treating the preliminary-cured material for 1 to 30 minutes at a treatment temperature from 30 to 85° C. The temperature for the swelling treatment is preferably within a range from 50 to 85° C. If the temperature for the swelling treatment is too low, long time is required for the swelling treatment, and a post-roughened adhesive strength between the cured object and the metal layer tends to be low.

For the roughening treatment, for example, a chemical oxidant such as a manganese compound, a chromium compound, or a persulfuric acid compound is used. Such chemical oxidants are added to water or an organic solvent and used as an aqueous solution or an organic solvent dispersed solution. A roughening liquid used for the roughening treatment generally contains an alkali as a pH adjuster etc. The roughening liquid preferably contains sodium hydroxide.

Examples of the manganese compound include potassium permanganate and sodium permanganate etc. Examples of the chromium compound include potassium dichromate and potassium chromate anhydrous etc. Examples of the persulfuric acid compound include sodium persulfate, potassium persulfate, and ammonium persulfate etc.

There is no particular limitation in the method for conducting the roughening treatment. A suitable method for the roughening treatment is, for example, a method of treating a preliminary-cured material once or twice using a 30 to 90 g/L permanganic acid or permanganate solution and a 30 to 90 g/L sodium hydroxide solution with a condition of treatment temperature of 30 to 85° C. for 1 to 30 minutes. The temperature for the roughening treatment is preferably within a range from 50 to 85° C.

An arithmetic mean roughness Ra of the roughening-treated surface of the roughened cured material is preferably not smaller than 50 nm, more preferably not larger than 350 nm, and further preferably not larger than 300 nm. A ten-point mean roughness of the roughening-treated surface of the roughened cured material is preferably not smaller than 500 nm, preferably not larger than 3.5 μm, and more preferably not larger than 3 μm. When such values of the arithmetic mean roughness Ra and the ten-point mean roughness Rz are indicated, it is possible to further increase the adhesive strength between the cured object and the metal layer and further to form further miniaturized wiring on the surface of the cured object layer.

(Desmear Treatment)

Furthermore, a penetration hole may be formed on the preliminary-cured material or the cured object. In the multilayer substrate, a via-hole or through-hole etc., is formed as the penetration hole. For example, it is possible to form the via-hole through irradiation of laser such as a CO₂ laser. There is no particular limitation in the diameter of the via-hole, and it is about 60 to 80 μm. By forming the penetration hole, a smear, which is a residue of resin derived from a resin component contained in a cured object layer, is often formed at the bottom within the via-hole.

In order to remove the smear, a desmear treatment is preferably conducted on the surface of the preliminary-cured material. The desmear treatment may also double as the roughening treatment. The desmear treatment is sometimes referred to as the roughening treatment.

Similar to the roughening treatment, for the desmear treatment, for example, a chemical oxidant such as a manganese compound, a chromium compound, or a persulfuric acid compound is used. Such chemical oxidants are added to water or an organic solvent, and used as an aqueous solution or an organic solvent dispersed solution. A desmear treatment liquid used for the desmear treatment generally contains an alkali. The desmear treatment liquid preferably contains sodium hydroxide.

There is no particular limitation in the method for conducting the desmear treatment. A suitable method for the desmear treatment is, for example, a method of treating a preliminary-cured material or a cured object once or twice using a 30 to 90 g/L permanganic acid or permanganate solution and a 30 to 90 g/L sodium hydroxide solution with a condition of treatment temperature of 30 to 85° C. for 1 to 30 minutes. The temperature for the desmear treatment is preferably within a range from 50 to 85° C.

In the following, the present invention will be described specifically with Examples and Comparative Examples. The present invention is not limited to the following Examples.

Materials shown in the following were used in the Examples and Comparative Examples.

(Epoxy Resin)

Bisphenol A type epoxy resin (“jER828” manufactured by Mitsubishi Chemical Corporation, epoxy equivalent: 185)

Biphenyl type epoxy resin (“NC-3000-H” manufactured by Nippon Kayaku Co., Ltd., epoxy equivalent: 275)

Triazine backbone-containing epoxy resin (“TEPIC-SP” manufactured by Nissan Chemical Industries, Ltd., epoxy equivalent: 100)

(Curing Agent)

Cyanate ester type curing agent solution (“BA230S75” manufactured by Lonza Japan Ltd., cyanate ester group equivalent: 235, methyl ethyl ketone is contained as a solvent,

solid content: 75 weight %)

Biphenyl type phenol curing agent (“MEH7851-H” manufactured by Meiwa Plastic Industries, Ltd., phenolic hydroxyl group equivalent: 223)

(Curing Accelerator)

Imidazole compound (1-cyanoethyl-2-phenylimidazole, “2PZ-CN” manufactured by Shikoku Chemicals Corporation)

(Filler)

Vinylsilane treated silica-containing slurry (“SO-C2” manufactured by Admatechs Co., Ltd., molten silica having a mean particle diameter of 0.5 μm, 100 parts by weight of the silica is surface-treated with 2.0 parts by weight of a vinylsilane coupling agent, “KBM-1003”, manufactured by Shin-Etsu Chemical Co., Ltd., cyclohexanone is contained as a solvent, solid content: 70 weight %)

Imidazole silane treated silica-containing slurry (“SO-C2” manufactured by Admatechs Co., Ltd., molten silica having a mean particle diameter of 0.5 μm, 100 parts by weight of the silica is surface-treated with 2.0 parts by weight of an imidazole silane coupling agent, “IM-1000”, manufactured by Nippon Mining & Metals Co., Ltd., N,N-dimethylformamide is contained as a solvent, solid content: 50 weight %)

### Example 1

(1) Production of Lamination Film

A resin composition varnish was obtained by mixing and agitating 85.7 parts by weight (60 parts by weight in solid content) of the vinylsilane treated silica-containing slurry, 18 parts by weight (13.5 parts by weight in solid content) of the cyanate ester type curing agent solution, 13 parts by weight of the bisphenol A type epoxy resin, 13 parts by weight of the biphenyl type epoxy resin, and 0.5 parts by weight of the imidazole compound at normal temperature until a uniform solution was obtained.

A release-processed and transparent polyethylene terephthalate (PET) film (“PET5011 550” manufactured by LINTEC Corporation, thickness: 50 μm) was prepared. The obtained resin composition varnish was coated on the release-processed surface of the PET film using an applicator, such that the thickness of the coating became 25 μm after drying. Next, the coated object was dried for 2 minutes in a gear oven at 100° C. to produce a lamination film of: an un-cured object (B stage film) of a resin sheet having a size of length 200 mm×width 200 mm×thickness 25 μm; and the PET film.

(2) Production of Roughened Cured Material

A copper substrate that was surface-treated with “CZ-8101” manufactured by MEC COMPANY LTD. was prepared. The obtained lamination film was set such that the un-cured object of the resin sheet was located on the copper substrate side. Pressure and heat were applied to the lamination film and the copper substrate for 1 minute at 0.5 MPa under a reduced pressure using a parallel plate pressing machine that had been heated to 100° C., to obtain a laminated body including a primary-cured material (preliminary-cured material) of the resin sheet. Then, the PET film was peeled off, and the laminated body was heated for 1 hour in a gear oven at 150° C. to obtain a laminated body A of the copper substrate and the primary-cured material.

On the primary-cured material in the laminated body A, the following (a) swelling treatment was conducted, and then the following (b) roughening treatment was conducted.

(a) Swelling Treatment:

The laminated body A was placed in a 60° C. swelling liquid (Swelling Dip Securiganth P, manufactured by Atotech Japan K.K.), and was shaken for 20 minutes. Then, the laminated body A was rinsed with pure water.

(b) Roughening Treatment:

The swelling-treated laminated body A was placed in a 80° C. roughening liquid (Concentrate Compact CP, manufactured by Atotech Japan K.K.), and was shaken for 25 minutes to obtain, on the copper substrate, a roughened cured material on which a roughening treatment had been conducted. The obtained roughened cured material was rinsed for 2 minutes with a 23° C. rinsing liquid (Reduction Securiganth P, manufactured by Atotech Japan K.K.), and then was rinsed again with pure water. Then, the roughened cured material was dried for 2 hours in a gear oven at 120° C. to obtain a roughened cured material B on which the roughening treatment had been conducted.

### Examples 2 to 4 and Comparative Examples 1 to 3

Lamination films and roughened cured materials B were obtained in the same manner as Example 1, except that the types and the blend amounts (parts by weight) of the used materials were changed as shown in the following Table 1.

(Evaluation)

(1) Image Observation 1

Gold sputtering was conducted on the roughening-treated surface of the obtained roughened cured material B by using a sputtering apparatus (“JFC-1600” manufactured by JEOL Datum Ltd.), in order to measure the following silica particle number A, the following silica particle number ratio B, and the following silica particle number ratio C. Next, the gold-sputtered surface of the roughened cured material was photographed in secondary electron image (5000 times) with a scanning electron microscope (“JSM-5610LV”, manufactured by JEOL Datum Ltd.) to obtain a photographed image. Evaluation was conducted for a 5 μm×5 μm sized area of the roughening-treated surface in the obtained image.

In the image, the number A of particles of the silica that were exposed from the roughening-treated surface and whose exposed portions had a maximum length of 0.3 μm or longer in the image was counted.

Furthermore, the ratio B of the number of particles of the silica that were exposed from the roughening-treated surface and whose exposed portions had a maximum length of 0.3 μm or longer in the image, to the total number of pores appearing in the image and silica particles appearing in the image, was obtained.

Moreover, the ratio C of the number of particles of the silica that were exposed from the roughening-treated surface and whose exposed portions had a maximum length of 0.3 μm or longer in the image, to the number of silica particles appearing in the image, was obtained.

(2) Image Observation 2

Gold sputtering was conducted on the roughening-treated surface of the obtained roughened cured material B by using a sputtering apparatus (“JFC-1600”, manufactured by JEOL Datum Ltd.), in order to measure the following residual silica particle number D, the following ratio E of pores receiving the residual silica, and the following ratio F of the residual silica. Next, the gold-sputtered surface of the roughened cured material was photographed in secondary electron image (5000 times) with a scanning electron microscope (“JSM-5610LV”, manufactured by JEOL Datum Ltd.) to obtain a photographed image. Evaluation was conducted for a 5 μm×5 μm sized area of the roughening-treated surface in the obtained image.

The number D1 of particles of the residual silica within the pores appearing in the image each of which particles had a maximum length of 0.3 μm or longer in the image, and the number D2 of particles of the residual silica within the pores appearing in the image each of which particles had a maximum length (μm), in the image, that was less than 0.3 μm and was equal to or larger than two-thirds of the maximum length (μm), in the image, of the pore receiving the residual silica, were counted. These particle numbers D1 and D2 were summed up to obtain the residual silica particle number D.

Furthermore, the ratio E1 of the number of pores each receiving the residual silica that was the residual silica within each pore appearing in the image and had a maximum length of 0.3 μm or longer in the image, to the total number of pores that appeared in the image and did not receive the residual silica and pores that appeared in the image and received the residual silica, and the ratio E2 of the number of pores each receiving the residual silica that was the residual silica within each pore appearing in the image and had a maximum length (μm), in the image, that was less than 0.3 μm and was equal to or larger than two-thirds of the maximum length (μm), in the image, of the pore receiving the residual silica, to the total number of the pores that appeared in the image and did not receive the residual silica and the pores that appeared in the image and received the residual silica, were obtained. These ratios E1 and E2 were summed up to obtain the ratio E of the pores receiving the residual silica.

Moreover, the ratio F1 of the number of pores each receiving the residual silica that was the residual silica within each pore appearing in the image and had a maximum length of 0.3 μm or longer in the image, to the number of pores that appeared in the image and received the residual silica, and the ratio F2 of the number of pores each receiving the residual silica that was the residual silica within each pore appearing in the image and had a maximum length (μm), in the image, that was less than 0.3 μm and was equal to or larger than two-thirds of the maximum length (μm), in the image, of the pore receiving the residual silica, to the number of the pores that appeared in the image and received the residual silica, were obtained. These ratios F1 and F2 were summed up to obtain the ratio F of the pores receiving the residual silica.

(3) Surface Roughness of Roughening-Treated Surface of Roughened Cured Material

The arithmetic mean roughness Ra and the ten-point mean roughness Rz of the roughening-treated surface of the roughened cured material were measured by using a non-contact three-dimensional profilometer (“WYKO NT1100”, manufactured by Veeco Instruments Inc.) according to JIS B0601-1994. The size of the measurement area was 94 μm×123 μm.

(4) Adhesive Strength

After the above (b) roughening treatment, the following (c) copper plating process was further conducted.

(c) Copper Plating Process:

Next, an electroless copper plating process and an electrolytic copper plating process were conducted with the following procedure on the obtained roughened cured material B.

The roughening-treated surface of the obtained roughened cured material B was treated for 5 minutes with a 55° C. alkaline cleaner (Cleaner Securiganth 902, manufactured by Atotech Japan K.K.) for delipidating and rinsing. After the rinsing, the roughened cured material was treated for 2 minutes with a 23° C. predip liquid (Pre-dip Neoganth B, manufactured by Atotech Japan K.K.). Then, the roughened cured material was treated for 5 minutes with a 40° C. activator liquid (Activator Neoganth 834, manufactured by Atotech Japan K.K.) to provide a palladium catalyst. Next, the roughened cured material was treated for 5 minutes with a 30° C. reduction liquid (Reducer Neoganth Wash., manufactured by Atotech Japan K.K.).

Next, the roughened cured material was placed in a chemically copper enriched liquid (Copper Solution Printganth MSK, manufactured by Atotech Japan K.K.), and electroless plating was conducted over 10 minutes until the thickness of the plating became about 0.5 μm. After the electroless plating, annealing was conducted for 30 minutes at a temperature of 120° C. in order to remove residual hydrogen gas, to obtain a cured material C on which the roughening treatment and the electroless plating had been conducted. It should be noted that all the steps from the alkali cleaner treatment to the electroless plating were conducted in a beaker scale where the treatment liquids were 1 L, and were conducted while the cured material B was shaken.

Electrolytic plating was conducted on the obtained cured material C at a current density of 1 A/dm² over 45 minutes until the thickness of the plating became about 20 μm. After the electrolytic plating, the cured material C was heated for 1 hour in a gear oven at 180° C. to obtain a laminated body D of the copper substrate and a secondary-cured material.

[Adhesive Strength Measuring Method]

A 10 mm width notch was made on the surface of the copper plating layer in the laminated body D. Then, an adhesive strength (peel strength) between the copper plating layer and the cured object was measured using a tensile testing machine (product name “Autograph”, manufactured by Shimadzu Corporation) with a condition of a crosshead speed of 5 mm/min.

The results are shown in the following Table 1. In addition, in the following Table 1, “total solid content A” represents the total solid content contained in the epoxy resin material.

TABLE 1

| | | | | | | Comp. | Comp. | Comp. |
|---|---|---|---|---|---|---|---|---|
| | | Ex. 1 | Ex. 2 | Ex. 3 | Ex. 4 | Ex. 1 | Ex. 2 | Ex. 3 |
| Blend component | Bisphenol A type epoxy resin | 13 | 8 | 20 | 13 | 13 | 13 | 16.5 |
| (parts by weight) | Biphenyl type epoxy resin | 13 | 8 | 6 | 13 | | | |
| | Triazine backbone-containing | | | | | 13 | 13 | 16.5 |
| | epoxy resin | | | | | | | |
| | Cyanate ester type curing agent | 18 | 11.3 | 18 | | 18 | | |
| | solution (contained amount | (13.5) | (8.5) | (13.5) | | (13.5) | | |
| | (weight %) of cyanate ester type | | | | | | | |
| | curing agent in 100 weight % of | | | | | | | |
| | total solid content A) | | | | | | | |
| | Biphenyl type phenol curing | | | | 13.5 | | 13.5 | 16.5 |
| | agent | | | | | | | |
| | Imidazole compound | 0.5 | 0.5 | 0.5 | 0.5 | 0.5 | 0.5 | 0.5 |
| | Vinylsilane treated silica- | 85.7 | 107.1 | 85.7 | 85.7 | 85.7 | 85.7 | |
| | containing slurry | | | | | | | |
| | Imidazole silane treated silica- | | | | | | | 120 |
| | containing slurry | | | | | | | |
| Contained amount (weight %) of all | | 60 | 75 | 60 | 60 | 60 | 60 | 50 |
| silica in 100 weight % of total solid | | | | | | | | |
| content A | | | | | | | | |
| Evaluation | (1) Number A | 5 | 10 | 5 | 2 | 20 | 30 | 40 |
| | (1) Ratio B (%) | 8 | 13 | 10 | 9 | 25 | 35 | 40 |
| | (1) Ratio C (%) | 25 | 38 | 29 | 27 | 60 | 70 | 75 |
| | (2) Number D1 | 4 | 7 | 5 | 2 | 12 | 20 | 43 |
| | (2) Number D2 | 5 | 8 | 4 | 3 | 12 | 25 | 32 |
| | (2) Number D | 9 | 15 | 9 | 5 | 24 | 45 | 75 |
| | (2) Ratio E1 (%) | 2 | 4 | 2 | 7 | 15 | 25 | 35 |
| | (2) Ratio E2 (%) | 2 | 4 | 2 | 11 | 15 | 31 | 26 |
| | (2) Ratio E (%) | 4 | 8 | 4 | 18 | 30 | 56 | 61 |
| | (2) Ratio F1 (%) | 11 | 19 | 12 | 16 | 27 | 28 | 40 |
| | (2) Ratio F2 (%) | 14 | 20 | 14 | 24 | 27 | 35 | 30 |
| | (2) Ratio F (%) | 25 | 39 | 26 | 40 | 54 | 63 | 70 |
| | (3) Arithmetic mean roughness | 100 | 150 | 100 | 80 | 250 | 350 | 450 |
| | Ra (mm) | | | | | | | |
| | (3) Ten-point mean roughness | 1.0 | 1.4 | 1.0 | 0.8 | 2.5 | 3.2 | 4.0 |
| | Rz (μm) | | | | | | | |
| | (4) Adhesive strength (N/cm²) | 5.0 | 4.5 | 4.5 | 5.0 | 3.5 | 4.5 | 5.0 |

### DESCRIPTION OF THE REFERENCE CHARACTERS

1 roughened cured material
1a first surface
1b second surface
1c pore
2 silica
6 lamination target object
6a upper surface
11 roughened cured material
11a first surface
11b second surface
11c pore
12 silica
12X residual silica
16 amination target object
16a upper surface
21 multilayer substrate
22 circuit board
22a upper surface
23 to 26 cured object layer
27 metal layer

1. A roughened cured material obtained by advancing curing of an epoxy resin material to obtain a preliminary-cured material and then conducting a roughening treatment on a surface of the preliminary-cured material, wherein
the epoxy resin material contains an epoxy resin, a curing agent, and a silica whose mean particle diameter is not smaller than 0.2 μm but not larger than 1.2 μm, and
when the roughening-treated surface is photographed with a scanning electron microscope, in a 5 μm×5 μm sized area of a roughening-treated surface in a photographed image, a number of particles of the silica that are exposed from the roughening-treated surface and whose exposed portions have a maximum length of 0.3 or longer in the image is not greater than 15.

2. The roughened cured material according to claim 1, wherein, when the roughening-treated surface is photographed with a scanning electron microscope, in a 5 μm×5 μm sized area of the roughening-treated surface in a photographed image, a ratio of a number of particles of the silica that are exposed from the roughening-treated surface and whose exposed portions have a maximum length of 0.3 μM or longer in the image, to a total number of pores appearing in the image and particles of the silica appearing in the image, is not greater than 20%.

3. The roughened cured material according to claim 1, wherein, when the roughening-treated surface is photographed with a scanning electron microscope, in a 5 μm×5 μm sized area of the roughening-treated surface in a photographed image, a ratio of a number of particles of the silica that are exposed from the roughening-treated surface and whose exposed portions have a maximum length of 0.3 μm or longer in the image, to a number of particles of the silica appearing in the image, is not greater than 50%.

4. The roughened cured material according to claim 1, wherein a contained amount of the silica in 100 weight % of total solid content contained in the epoxy resin material is not less than 55 weight % but not greater than 80 weight %.

5. The roughened cured material according to claim 1, wherein an arithmetic mean roughness Ra of the roughening-treated surface is not larger than 0.3 μm, and a ten-point mean roughness Rz of the roughening-treated surface is not larger than 3.0 μm.

6. The roughened cured material according to claim 1, wherein a swelling treatment is conducted on the preliminary-cured material before the roughening treatment is conducted.

7. A laminated body comprising:
a cured object resulting from curing the roughened cured material according to claim 1; and
a metal layer laminated on a roughening-treated surface of the cured object.

8. The laminated body according to claim 7, wherein an adhesive strength between the cured object and the metal layer is not less than 3.9 N/cm².
